(19) United States
(12) Patent Application Publication
(10) Pub. No.: US 2003/0041891 A1
(43) Pub. Date: Mar. 6, 2003

(54) Lamp set with electric power generating device incorporating thermocouple

(76) Inventor: Pedro Monsanto, Brussels (BE)

Correspondence Address: ROSENBERG, KLEIN & LEE, 3458 ELLICOTT CENTER DRIVE-SUITE 101, ELLICOTT CITY, MD, 21043, US

(21) Appl. No.: 09/942,650

(22) Filed: Aug. 31, 2001

(51) Int. Cl. H01L 35/30; H01L 35/02

(52) U.S. Cl. 136/205

(57) ABSTRACT

A lamp set with a thermal converting device is disclosed. The thermal converting device includes a supporting frame having a heat-generating source mounted therein, a thermal converting mechanism located on a top opening of the supporting frame, and a thermocouple mounted in the thermal converting mechanism with a hot end of the thermocouple adjacent to a central through hole of the thermal converting mechanism and a cold end contacting with a radiating member provided around the central through hole. When the heat-generating source generates heat energy to heat the hot end, a potential difference between the hot and the cold ends of the thermocouple is generated and led out via conductors to supply electric energy to an electric load connected to the thermal converting device.

### BACKGROUND OF THE INVENTION

1. Field of the Invention

The present invention relates to a lamp set, and more particularly to a lamp set with a thermal converting device that includes a thermocouple element.

2. Description of the Prior Art

It is known the thermocouple has been widely employed in many products of different application fields, and techniques related to thermocouples have been highly developed. A thermocouple includes a hot end and a cold end having a temperature difference existing between them. This temperature difference produces a potential difference at an output of the thermocouple and the potential difference may be led out via conductors for use in different applications. For example, the potential difference, which is an analogue signal, may be converted into a digital signal via an analog-to-digital converter (ADC). The converted digital signal could then be further processed via a digital circuit known in the art. Moreover, the analogue signal of a potential difference may also be used to supply electric energy needed by a small electric load to work or to charge an energy storage circuit or an energy storage element.

It is true that most electric loads, such as radio, mobile phone, lighting fixture, etc., obtain required electric energy from the power supplied by utility facility. However, there are places at where the power from the utility facility is not available. At this point, rechargeable batteries or dry batteries are relied on to supply the electric energy needed by such electric loads. However, it would be more convenient if electric energy could be obtained outdoors through other ways, such as solar energy, thermal energy, etc.

For example, portable lighting devices and radio and other small electric loads are frequently used in many outdoor activities, such as camping. It would be more convenient and interesting if a portable lighting device were provided with additional function of converting thermal energy into electric energy for use by other electric loads usually needed in the outdoor activities.

In particular, when a mobile phone becomes battery low in an outdoor activity, a thermal converting device would be much helpful to charge the battery of the mobile phone in an emergency. Thus, a thermal converting to device adapted to generate heat energy and convert the same into electric energy is particularly useful for isolated areas and underdeveloped regions at different comers of the world.

### SUMMARY OF THE INVENTION

It is therefore a primary object of the present invention to provide a thermal converting device for converting heat energy into electric energy for use by electric loads.

Another object of the present invention is to provide a thermal converting device that usually functions as a lighting fixture and is adapted to convert heat produced by the device into electric energy for use by a small electric load.

To achieve the above and other objects, the thermal converting device of the present invention mainly includes a supporting frame having a heat-generating source mounted therein, a thermal converting mechanism located on a top opening of the supporting frame, and a thermocouple mounted in the thermal converting mechanism with a hot end of the thermocouple adjacent to a central through hole of the thermal converting mechanism and a cold end contacting with a radiating member provided around the central through hole. When the heat-generating source generates heat that is upward transferred to the central through hole of the thermal converting mechanism to heat the hot end, a potential difference between the hot and the cold ends of the thermocouple is formed and led out via conductors to supply electric energy needed by an electric load connected to the thermal converting device.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a thermal converting device according to the present invention;

FIG. 2 is an exploded perspective view of FIG. 1;

FIG. 3 is a sectional view taken along line A-A of FIG. 2, showing the structure of the thermal converting mechanism included in the present invention and the location of a thermocouple in the thermal converting mechanism; and

FIG. 4 is an elevational view of the thermal converting device of the present invention in use.

### DETAILED DESCRIPTION OF THE PREFERRED EMBODIMENTS

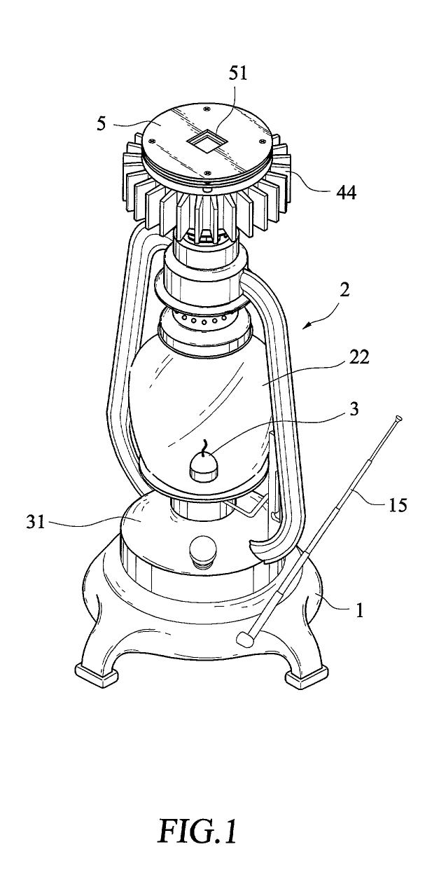

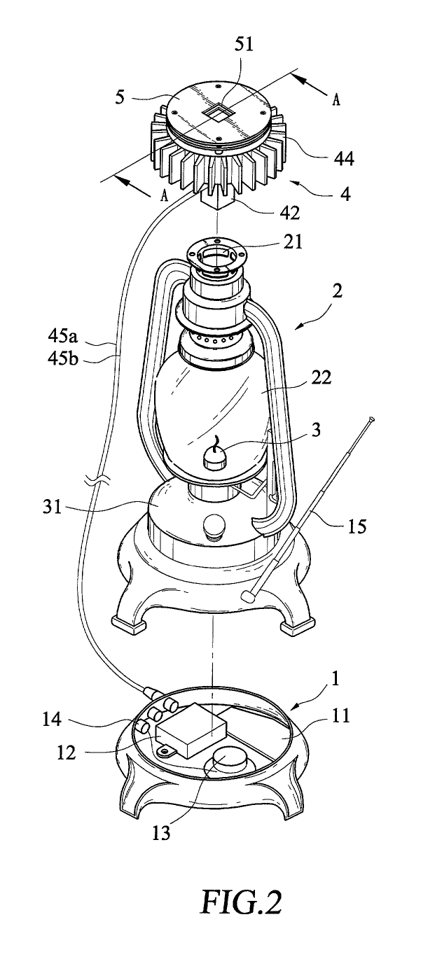

Please refer to FIGS. 1 and 2 that are assembled and exploded perspective views, respectively, of a thermal converting device according to a preferred embodiment of the present invention. As shown, the thermal converting device mainly includes a base 1 serving as a foundation of the entire device and defining an internal space for accommodating a circuit board 11, a rechargeable battery 12, a speaker 13, and other related electronic components and parts therein. The base 1 is provided at a wall portion thereof with at least one power-output jack 14 to which an external electric load may be connected. On the circuit board 11, there is provided with an electric load. In an embodiment of the present invention, the electric load connected to the circuit board 11 is a radio equipped with an antenna 15.

The thermal converting device of the present invention also includes a supporting frame 2 located above the base 1 and having a top opening 21.

In the preferred embodiment of the present invention, the supporting frame 2 includes a transparent hollow cylindrical body 22 defining an inner space for a light-emitting means, such as an oil-burning lamp 3 or other similar gas-burning lamp, to mount therein. In addition to function as a lighting fixture in the thermal converting device of the present invention, the oil-burning lamp 3 also functions as a heat-generating source. An oil storage 31 is provided between the supporting frame 2 and the base 1 for storing therein an amount of fuel, such as kerosene or gasoline, needed by the oil-burning lamp 3. The heat-generating source is not necessarily an oil-burning lamp 3. Other types of means, such as a candle, an alcohol lamp, etc., may also be used as the heat-generating source.

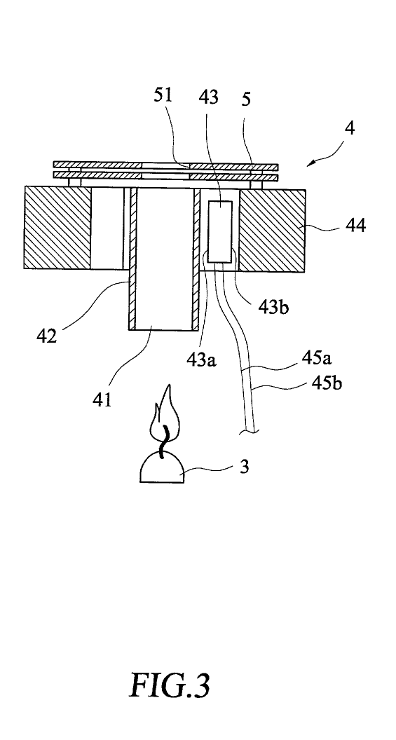

A thermal converting mechanism 4 is provided at a top of the supporting frame 2. Please refer to FIG. 3 that is a sectional view of the thermal converting mechanism 4. As shown, the thermal converting mechanism 4 includes a central through hole 41 corresponding to and in alignment with the top opening 21 of the supporting frame 2, so that heat generated by the oil-burning lamp 3 in the supporting frame 2 is upward transferred to the top opening 21 and the central through hole 41. A heat-transfer member 42 is inserted in the central through hole 41 with a lower end downward extended from the hole 41 for guiding and transferring heat generated by the oil-burning lamp 3 to a thermocouple 43 located at one side of the central through hole 41. A radiating member 44 is provided around the central through hole 41 and the thermocouple 43. The thermocouple 43 includes a hot end 43a facing toward the central through hole 41 and contacting with a wall surface of the heat-transfer member 42, and a cold end 43b facing away from the central through hole 41 and contacting with the radiating member 44.

A first conductor 45a is connected at an end to the hot end 43a of the thermocouple 43 and a second conductor 45b is connected at an end to the cold end 43b of the thermocouple 43. The other ends of the first and the second conductors 45a, 45b are connected to a power-in end of the circuit board 1 in the base 1, so that electric energy generated by the thermocouple 43 is led to the circuit board 11.

When the oil-burning lamp 3 in the supporting frame 2 is lighted up, it not only emits light in the night, but also generates heat that is transferred to the top opening 21 of the supporting frame 2 and the central through hole 41 of the thermal converting mechanism 4 to heat the hot end 43a of the thermocouple 43. Meanwhile, the cold end 43b of the thermocouple 43 keeps cold due to the radiating member 44 that is in contact with the cold end 43b and provides good radiating effect. Therefore, a potential difference exists between the hot end 43a and the cold end 43b of the thermocouple 43 due to a temperature difference therebetween. The potential difference is led out via the first and the second conductors 45a, 45b to the circuit board 11 in the base 1 to supply an electric energy needed by the circuit board 11.

The electric energy produced by the thermocouple 43 may also be used to charge the rechargeable battery 12. When the thermocouple 43 is not in the state of producing electric energy, electric energy stored in the rechargeable battery 12 may be supplied to the electric load connected to the circuit board 11.

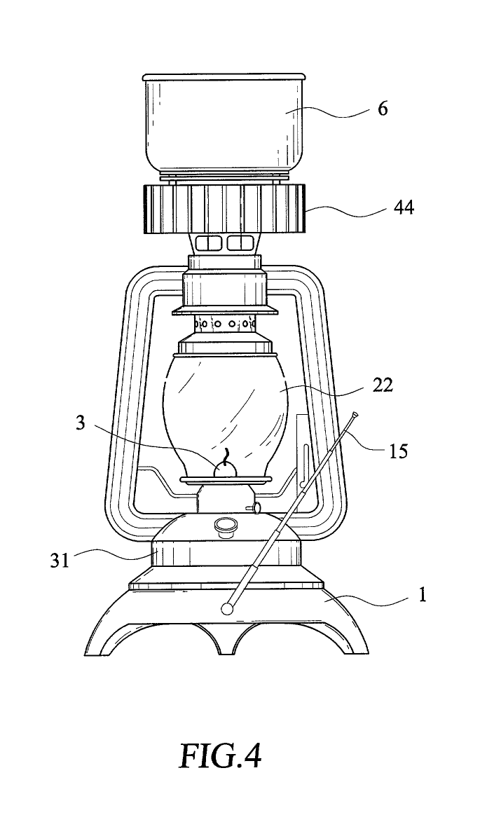

A heat-transfer plate 5 having a central area cut away to form a central opening 51 is further provided at a top of the thermal converting mechanism 4. When the thermal converting device of the present invention is used outdoors, a metal container 6 may be positioned on the heat-transfer plate 5, as shown in FIG. 4, so that thermal energy generated by the oil-burning lamp 3 also warms up or heat the metal container 6 and food contained therein. The thermal converting device of the present invention is therefore useful in outdoor activities to increase the fin thereof. In another embodiment of the present invention, the supporting frame 2 may be provided with handles or a pair of ears (not shown), so that the thermal converting device of the present invention may be conveniently portable or hung over some desired position.

With the above arrangements, the thermal converting device of the present invention is highly practical for use and functions in a manner that has never been found in any other prior art.

What is claimed is:

1. A thermal converting device adapted to generate a thermal energy and convert the thermal energy into an electric energy for use by an electric load, comprising:
a base;
a supporting frame being located on a top of said base and having a top opening;
a heat-generating source being mounted in said supporting frame for generating an amount of heat energy;
a thermal converting mechanism mounted on the supporting frame, having a central through hole corresponding to and in alignment with said top opening of said supporting frame, such that said heat energy generated by said heat-generating source is upward transferred to said top opening of said supporting frame and said central through hole of said thermal converting mechanism, and a radiating member being provided around said central through hole; and
a thermocouple being mounted in said thermal converting mechanism adjacent to one side of said central through hole of the thermal converting mechanism, and having a hot end facing toward said central through hole and a cold end facing away from said central through hole to contact with said radiating member;
a pair of conductors, one of the conductors which being connected to the hot end of the thermocouple, and the other conductor being connected to the cold end of the thermocouple; and
said heat energy generated by said heat-generating source and upward transferred to said top opening of said supporting frame and said central through hole of said thermal converting mechanism heating up said hot end of said thermocouple that is adjacent to said central through hole, resulting in a potential difference between said hot and said cold ends of said thermocouple, and said potential difference being led out via said first and said second conductors to supply an electric energy needed by said electric load.

2. The thermal converting device as claimed in claim 1, wherein said supporting frame comprises a transparent hollow cylindrical body that defines an inner space for accommodating said heat-generating source therein.

3. The thermal converting device as claimed in claim 1, wherein said heat-generating source is an oil-burning lamp.

4. The thermal converting device as claimed in claim 1, wherein said heat-generating source is a gas-burning lamp.

5. The thermal converting device as claimed in claim 1, wherein said thermal converting mechanism comprises a heat-transfer member provided in said central through hole with a lower end of said heat-transfer member downward extended from said central through hole by a predetermined length for guiding and transferring heat energy generated by said heat-generating source to said central through hole.

6. The thermal converting device as claimed in claim 1, wherein said base is provided therein with a circuit board for said electric load to electrically connect thereto; said circuit board being provided with two terminals connected to said first and said second conductors for leading said electric energy generated by said thermocouple into said circuit board.

7. The thermal converting device as claimed in claim 6, wherein said circuit board is electrically connected via said first and said second conductors to at least one power-output jack, and said at least one power-output jack being fixedly provided on a wall portion of said base.

8. The thermal converting device as claimed in claim 1, wherein said base is provided therein with a rechargeable battery and said electric energy generated by said thermocouple is transferred via said first and said second conductors to charge said rechargeable battery, and wherein said rechargeable battery is adapted to supply electric energy stored therein to said electric load when said thermocouple is not in a state of generating electric energy.

9. The thermal converting device as claimed in claim 1, wherein said electric load is a radio.

10. The thermal converting device as claimed in claim 1, wherein said thermal converting mechanism has a heat-transfer plate mounted to a top thereof, and said heat-transfer plate having a central area being cut away to form a central opening.
